(19) United States
(12) Patent Application Publication
(10) Pub. No.: US 2002/0135983 A1
(43) Pub. Date: Sep. 26, 2002

(54) Energy conversion apparatus

(76) Inventors: Christpher Freitas, Mount Vernon, WA (US); Robert Dean Gudgel, Everett, WA (US); Amar Kant Nanda, Surrey (CA); Robin Wayne Gudgel, Arlington, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 09/812,073

(22) Filed: Mar. 20, 2001

(51) Int. Cl. H05K 7/20

(52) U.S. Cl. 361/704; 363/141

(57) ABSTRACT

An energy conversion apparatus comprising a heat conductive base, a heat insulating cover operable to mate with the base so as to form a sealed space bounded by the cover and the base to prevent ingress of moisture, and a mount inside the space, for securing an energy conversion circuit to at least one of the cover and the base.

### BACKGROUND OF THE INVENTION

1. Field of Invention

This invention relates to energy conversion apparatus and more particularly to electrical energy conversion apparatus designed to operate in conjunction with batteries.

2. Description of Related Art

Many vehicles employ lead-acid or gel batteries for starting or for deep cycle operations. Such vehicles normally have space specifically designated for receiving and/or mounting such batteries and many provide for receiving or mounting a plurality of batteries. With the advent of efficient, low cost energy conversion devices such as inverters and chargers many vehicle owners desire to add these devices to their vehicles. However, space is limited on vehicles and often, there is no suitable place to mount or position such devices, thus limiting the owner's ability to make use of them.

What would be desirable is energy conversion device that is easy and convenient to mount in harsh environment areas on a vehicle.

### SUMMARY OF THE INVENTION

The present invention addresses the above needs by providing an electrical energy conversion apparatus having a heat conductive base, a heat insulating cover operable to mate with the base so as to form a sealed space bounded by the cover and the base to prevent ingress of moisture, and a mount inside the space, for securing an energy conversion circuit to at least one of the cover and the base.

The energy conversion circuit may include an inverter and/or a battery charger.

The apparatus may further include a drain for draining liquid from inside the space and may have a battery form factor such as a generally rectangular parallelepiped shape enabling the apparatus to occupy a space occupiable by a battery and may further include provisions for securing the apparatus in the space occupiable by a battery.

The apparatus may also include a vent in at least one of the base and the cover for venting humid air from the space. The vent may be located in the base and may include a moisture permeable membrane allowing moisture to pass from the space to an area outside the apparatus.

The apparatus may also include a drain comprising an opening in the base and a resilient seal covering the opening. The resilient seal may be movable in response to a pressure difference between the sealed space and ambient pressure to allow fluid to pass through the opening.

The base and/or the cover may have sealable openings through which electrical conductors of the energy conversion circuit may pass. The cover may be formed from plastic and the base may be formed from metal and may have provisions for mounting the apparatus to a battery mount. The base may further have a transformer mount, for mounting a transformer of the energy conversion circuit.

The apparatus may include an energy conversion circuit mounted in an airspace inside the sealed space and may include a plurality of switching devices configured to reduce heat generation sufficient to permit the energy conversion circuit to operate while the apparatus is in an area having an ambient temperature range between about −40 degrees centigrade to about +85 degrees centigrade. The plurality of switching devices may include a plurality of transistors connected in parallel.

The energy conversion circuit may further include a transformer configured to reduce heat generation sufficient to permit the energy conversion circuit to operate while the apparatus is the above mentioned temperature range. The energy conversion circuit may also include a plurality of circuit boards and a vibration damper for dampening vibrations of the circuit boards. The vibration damper may include supports extending between the circuit boards. One support may include a guide and at least one of the circuit boards may have an opening for co-operating with the guide to guide the at least one circuit board in sliding movement relative to the other.

The mount for mounting the energy conversion circuit may include holders in the base and/or in the cover for holding circuit boards of the energy conversion device in spaced apart relation while permitting the at least one circuit board to move relative to the other, to facilitate sealing between components on the circuit boards and the cover while permitting access to the components, from outside the cover.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is an isometric view of an energy conversion apparatus according to a first embodiment of the invention;

FIG. 2 is an isometric view of a base shown in FIG. 1;

FIG. 3 is an isometric view of a cover shown in FIG. 1;

FIG. 4 is an isometric view of the base shown in FIG. 1 with an energy conversion circuit installed therein;

FIG. 5 is an isometric view of a vent of the apparatus shown in FIG. 1;

FIG. 6 is a schematic diagram of a battery charger according to one embodiment of the invention;

FIG. 7 is a schematic diagram of an inverter according to an alternate embodiment of the invention; and

FIG. 8 is a schematic diagram of an inverter/charger according to an alternate embodiment of the invention.

### DETAILED DESCRIPTION

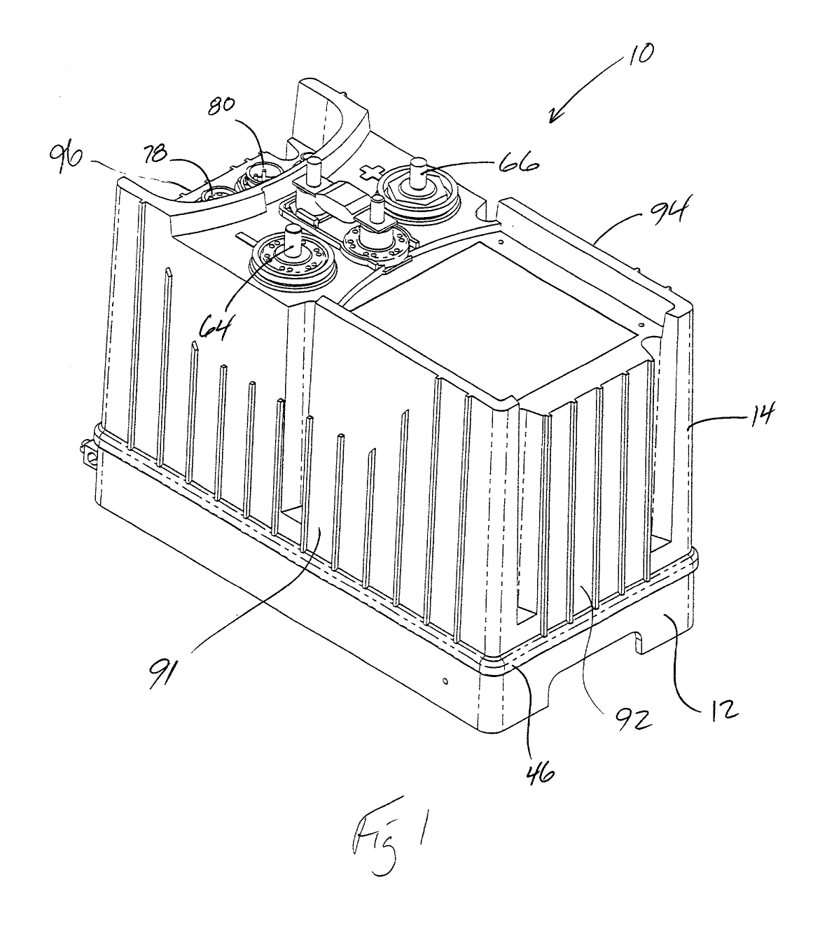

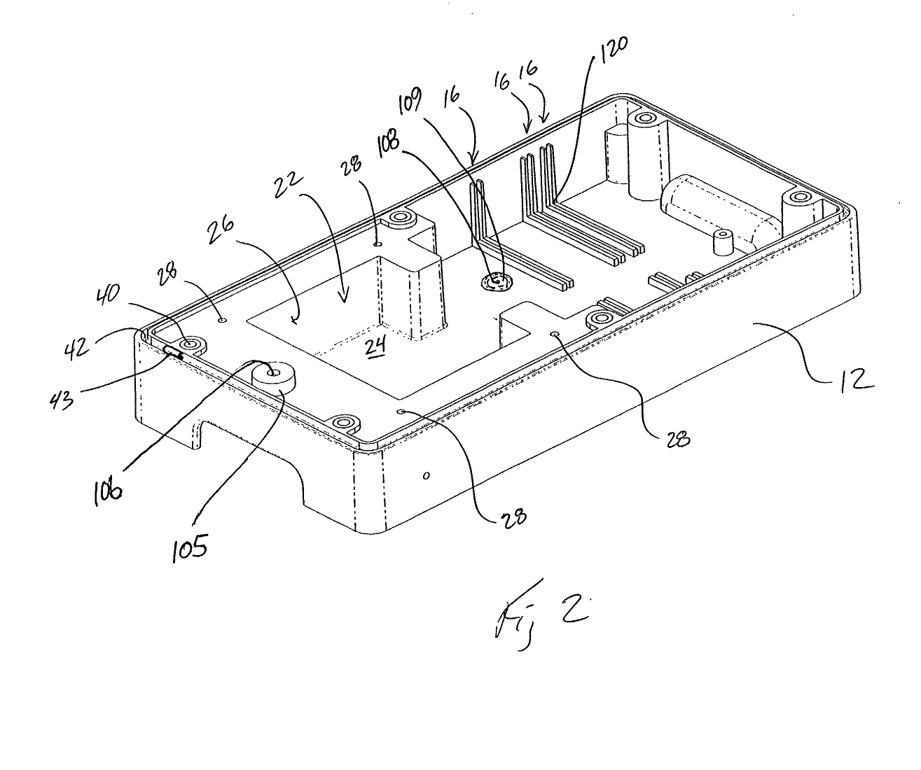

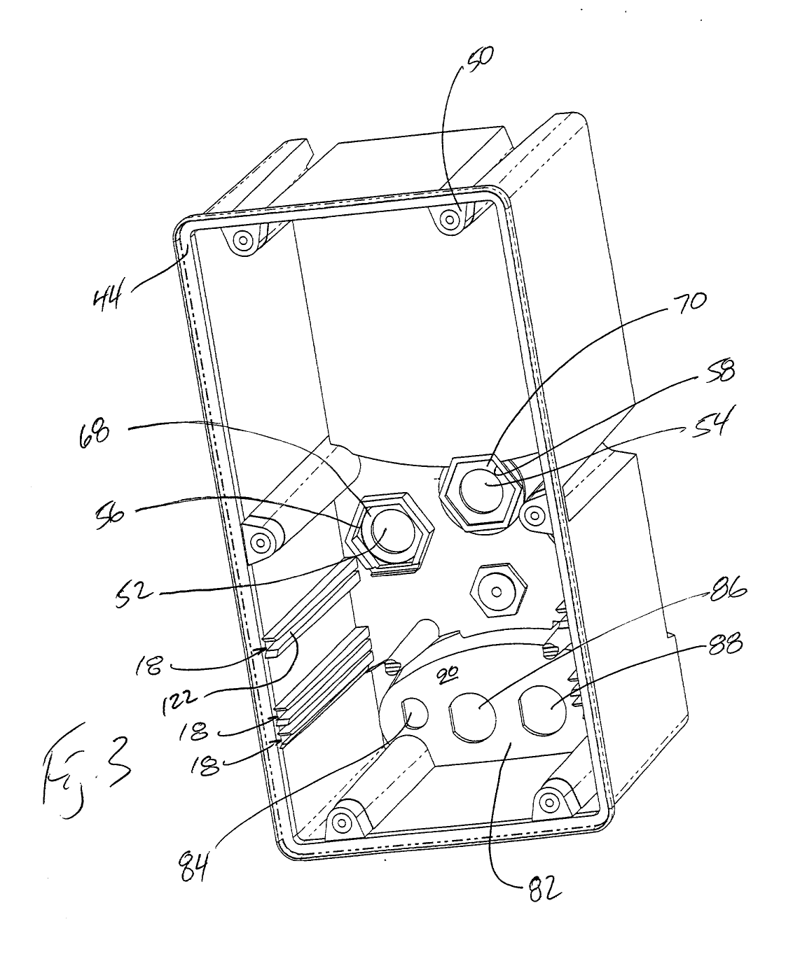

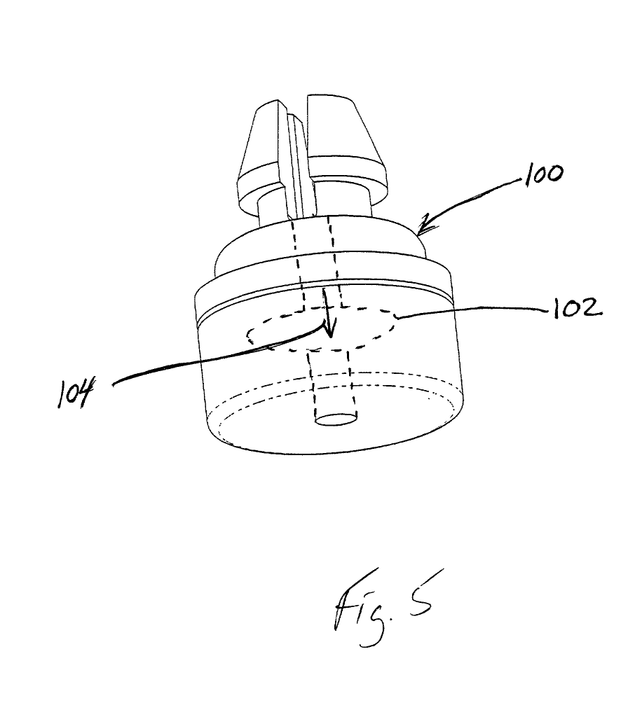

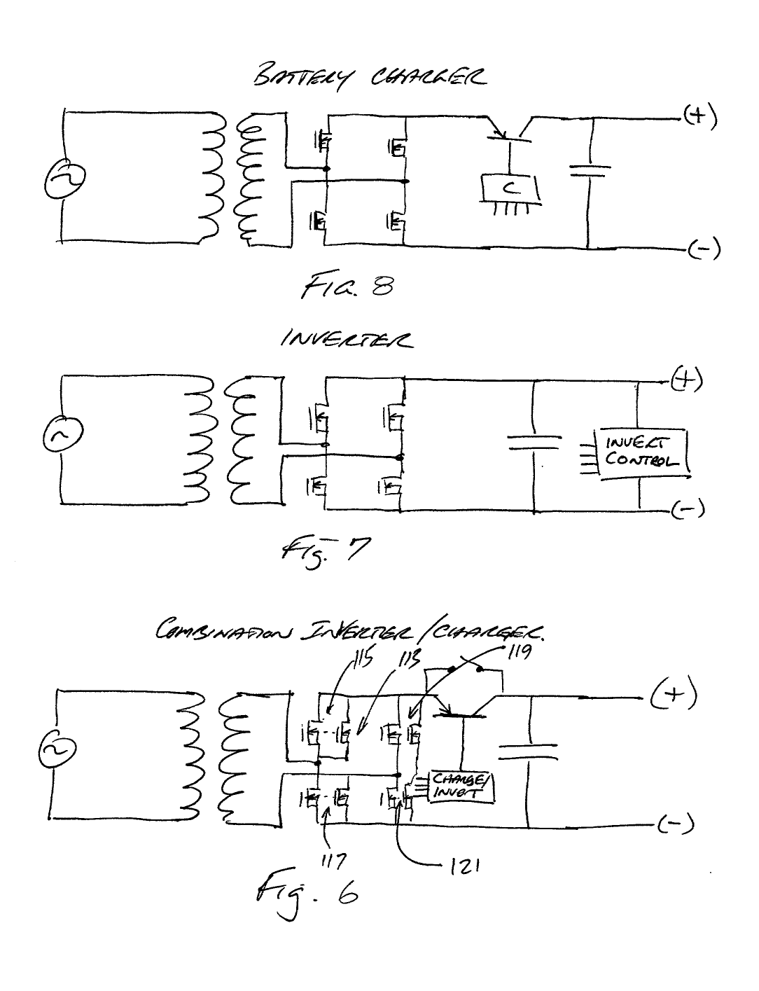

Referring to FIG. 1, an electrical energy conversion apparatus according to a first embodiment of the invention is shown generally at 10. The apparatus 10 comprises a heat conductive base 12, a heat insulating cover 14 operable to mate with the base so as to form a sealed space bounded by the cover and the base 12, to prevent ingress of moisture, and referring to FIGS. 2 and 3, the apparatus further includes a mount, which in this embodiment includes holders shown generally at 16 in the base 12 as shown in FIG. 2 and holders shown generally at 18 in the cover 14 as shown in FIG. 3. The holders 16 and 18 are operable to secure an energy conversion circuit shown generally at 20 in FIG. 4 to at least one of the cover 14 and the base 12. In particular, the holders 16 and 18 may hold a plurality of circuit boards of the energy conversion circuit 20, in spaced apart relation. In this embodiment, the energy conversion circuit 20 shown in FIG. 4 includes a combination battery charger and an inverter as shown in FIG. 6, but could alternatively just comprise an inverter as shown in FIG. 7 or just a charger as shown in FIG. 8, or could include any other type of electrical energy conversion device. In this embodiment, the energy conversion circuit comprises a transformer 30 and a plurality of circuit boards 110, 112 and 114.

Referring to FIG. 2, the base 12, in this embodiment, is formed of a heat conductive metal, such as aluminum, for example. The base 12 may be cast and machined to include the mounts 16, for example. In this embodiment, the base 12 further includes a transformer mount 22 including a cavity 24 bounded by a wall 26 having mounting openings 28 therein for securing the transformer 30 of the energy conversion circuit thereto.

Referring to FIG. 4, the transformer 30 is mounted to the wall portion 26 such that an opposite portion of a winding 32 of the transformer is received in the cavity 24 shown in FIG. 2. The wall 26 shown in FIG. 2 is solid metal and when the transformer 30 shown in FIG. 4 is mounted to the wall using screws 34, for example, heat dissipated by the windings 32 and transformer core 36 is transferred to the base 12 with low thermal resistance. In this embodiment, the transformer 30 is designed for high temperature operation and is configured to reduce heat generation sufficient to permit the energy conversion circuit to operate while the apparatus is in an ambient temperature range of between about −40 degrees centigrade to about +85 degrees centigrade. This is a typical operating temperature range of an engine compartment of a conventional passenger vehicle. To achieve this temperature range, the transformer has heavy gauge windings to reduce electrical resistance and a heavy core to reduce eddy current losses.

In addition, the energy conversion circuit 20 includes a plurality of switching devices 113 mounted on the circuit boards, in this embodiment the third circuit board 114. The switching devices are configured to reduce heat generation sufficient to permit the energy conversion circuit 20 to operate within the above indicated temperature range. In particular, this is achieved by connecting at least some of the plurality of switching devices 113 in parallel. Referring to FIG. 6, in this embodiment, the energy conversion circuit 20 includes a combination inverter/charger which has four “switching” legs 115, 117, 119, 121. Each switching leg is comprised of twelve metallic oxide semiconductor field effect transistors (MOSFETs) connected in parallel to provide a very low “on” resistance in each leg, which reduces heat dissipation. The use of the above described transformer mounting method, the transformer 30 and the arrangement of switching devices 113 reduces the amount of heat generated by the energy conversion circuit 20, enabling it to maintain operation in the sealed environment provided by the base 12 and cover 14, when the apparatus 10 is operated in the above described ambient temperature range.

Referring back to FIGS. 1 and 2, the base 12 also has a plurality of receptacles, one of which is shown at 40, for receiving fasteners from an underside of the base, to engage with the cover 14. The base 12 also has a perimeter groove 42 for receiving a complementary shaped rubber seal, only a portion of which is shown at 43 therein, and referring to FIG. 3, the cover has a shoulder portion 44 which presses the seal into the groove 42 such that the seal 43 acts as a sealing gland in the groove, to prevent the ingress of moisture and/of dirt and/or chemical contaminants into the space bounded by the base 12 and the cover 14.

Referring to FIG. 1, the cover 14 is formed from an ABS/polycarbonate plastic which makes it resistant to chemicals such as battery acid. The cover 14 is shaped to have a lip 46 which extends partially over the top perimeter of the base 12, such that any water or liquid running down the cover is deflected away from a joint formed between the base and the cover.

Referring to FIG. 3, the inside of the cover has a plurality of bosses, one of which is shown at 50, for receiving fasteners inserted through openings such as 40 in the base 12, to secure the cover 14 to the base. In this embodiment screws may be used to hold the cover to the base. The openings 40 may be sealed by O rings 51 or sealing compound, for example.

Referring to FIGS. 2 and 3, in this embodiment, the holders 16 and 18 are in the form of L-shaped slots, one of which is shown at 120 in FIG. 2. Referring to FIGS. 2 and 4, the circuit boards 110, 112 and 114 are slidingly received in these slots 120 such that the circuit boards may slide and be held therein, in the orientation shown in FIG. 4. It will be appreciated that, referring to FIG. 4, when the cover 14 is placed over the base 12 as shown in FIG. 1, slots such as 122 shown in FIG. 3 receive edges of the circuit boards 110, 112 and 114 respectively.

In this embodiment, the energy conversion circuit includes two circuit boards 110 and 114 which have components which must be accessible from outside of the cover, as shown in FIG. 1. Due to tolerance stacking as a result of the mechanical tolerances which add up over the length of the circuit boards, it is desirable to mount the two circuit boards 110 and 114 so that they remain substantially parallel, but at least one of the circuit boards can be vertically displaced relative to the other circuit board. Providing vertical displacement between the circuit boards facilitates sealing between the cover 14 and the externally accessible components on the first circuit board 110 and simultaneously facilitates sealing between the cover and the externally accessible components on the third circuit board 114.

A vibration damper extends between respective circuit boards, and in this embodiment the damper includes supports 116 and 118 extending between the circuit boards. In this embodiment, the supports are provided by threaded standoffs.

To facilitate relative movement of the circuit boards 110 and 114, in this embodiment the support for the first circuit board 110 includes a guide, which in this embodiment is provided by a screw 128 receivable in an opening which in this embodiment is an elongated slot 130 in the first circuit board 110 which co-operates with the guide to guide the circuit board 110 in sliding movement relative to the second and third circuit boards 112 and 114.

The cover 14 has a top portion 51 having openings 52 and 54 having hexagonal walls 56 and 58 respectively formed therearound, for receiving respective hexagonal nut members 60 and 62 of first and second conductors shown generally at 64 and 66, on the third circuit board 114, which are to be accessible from outside the cover. Rubber washers as shown at 68 and 70 are received in the areas bounded by the hexagonal walls 56 and 58 respectively, such that when the conductors 64 and 66 are received through the openings 52 and 54, the rubber washers 68 and 70 are compressed between the nut members 60 and 62 and the top portion 51, thereby sealing the area around the conductors, relative to the cover 14, to prevent ingress of moisture into the space bounded by the cover and base 12. The conductors may be configured to pass through either the cover 14 or the base 12, provided the openings are sealed. The sealing method shown in FIGS. 3 and 4 is simply an exemplary sealing method.

The first circuit board 110 has externally accessible components including switches 74 and 76 for controlling the operation of the energy conversion circuit and connectors 78 and 80 for connecting to a remote control panel and for connection to an AC bus respectively. To suit these components, referring to FIG. 3, the cover 14 has a mating connector portion 82 disposed in a plane spaced apart from the top portion 51 and having openings, only three of which are shown at 84, 86 and 88, for receiving the switches 74 and 76 and connectors 78 and 80 therethrough. The switches and connectors may be fitted with rubber gaskets, which mate with the surface 90 of the connector portion 82 so as to form a seal around the connectors and switches to prevent the ingress of moisture into the space bounded by the cover 14 and the base 12. Since the first circuit board 110 is movable relative to the third circuit board 114 positioning of the connector portion 82 relative to the components for sealing while maintaining a seal on the externally accessible components on the third circuit board 114 is not seriously affected by tolerance stacking on the circuit boards and a good seal around all externally accessible components can be achieved.

Referring to FIGS. 3 and 4, it will be appreciated that the sealed space bounded by the cover 14 and base 12 is an air space and, as such, there is a possibility that the air inside the sealed space may become humid. However, the heat insulating cover 14 and heat conducting base 12 cooperate to reduce condensation on the inside surfaces of the cover and keep any condensation on or near the base 12. To facilitate removal of humid air from the air space, at least one of the base 12 and the cover 14 is provided with a vent and in this embodiment, referring to FIG. 4, the vent is shown at 100 on the base 12.

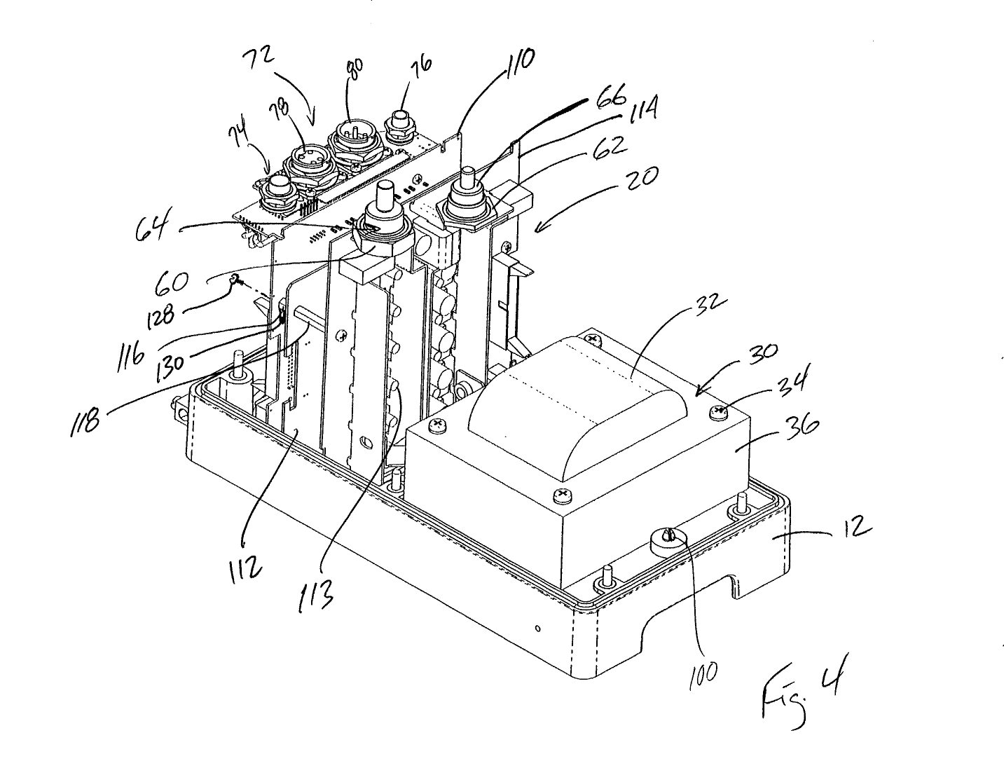

Referring to FIG. 5, in this embodiment the vent 100 is a UNIVENT® manufactured by W.L. Gore & Associates, Automotive Products Group. The vent 100 includes a moisture permeable Gore-Tex® membrane 102 allowing moisture to pass in the direction of arrow 104 from the space bounded by the cover 14 and the base 12 to an area outside the apparatus 10. Referring to FIG. 2, the base 12 may be formed with a boss 105 having an opening 106 for receiving and holding the UNIVENT as shown in FIG. 4.

Referring to FIG. 2, to further facilitate removal of moisture from the sealed space, the base 12 may be fitted with a drain having an opening 108, which is preferably positioned at a lowest point in the base. Thus any liquid which condenses on the base, runs to the drain and any air pressure buildup within the space, due to heating of the components of the energy conversion circuit 20, causes a resilient seal 109 covering the opening to open slightly in response to a pressure difference between the sealed space and ambient pressure, to permit the liquid to be expelled.

Referring to FIG. 1, when the cover 14 is mounted to the base 12, the cover and base have a generally rectangular parallelepiped shape, although walls 91, 92, 94 and 96 of the cover are slightly inwardly tapered toward a top portion of the cover 14. The cover 14 and base 12 are formed so as to generally have a conventional lead acid battery form factor which enables the apparatus to occupy a space which would normally be occupiable by a lead acid battery. Thus, the apparatus 10 effectively provides a housing for the energy conversion circuit 20 and the housing has a form factor enabling the apparatus to be installed in a position normally occupied by a conventional lead acid battery. The conductors 64 and 66 protrude from the cover 14 in a manner similar to that in which battery posts protrude from a battery, thus facilitating easy connection of the conductors 64 and 66 to adjacent batteries, with short leads. The sealing engagement between the cover 14 and the base 12 and the sealing around the conductors 64 and 66 and switches 74 and 76 and connectors 78 and 80 render the apparatus 10 spray resistant enabling it to withstand pressure washing and rugged physical conditions including ambient heat and humidity extremes and vibration. Consequently, the apparatus 10 is quite suitable for mounting on a vehicle subjected to these extremes.

While specific embodiments of the invention have been described and illustrated, such embodiments should be considered illustrative of the invention only and not as limiting the invention as construed in accordance with the accompanying claims.

What is claimed is:

1. An energy conversion apparatus comprising:
a heat conductive base;
a heat insulating cover operable to mate with the base so as to form a sealed space bounded by the cover and the base to prevent ingress of moisture; and
a mount inside the space, for securing an energy conversion circuit to at least one of said cover and said base.

2. The apparatus as claimed in claim 1 further comprising a vent in at least one of said base and said cover for venting humid air from said space.

3. The apparatus as claimed in claim 2 wherein said vent is located in said base.

4. The apparatus as claimed in claim 3 wherein said vent includes a moisture permeable membrane allowing moisture to pass from said space to an area outside the apparatus.

5. The apparatus as claimed in claim 1 further comprising a drain for draining liquid from inside said space.

6. The apparatus as claimed in claim 5 wherein said drain comprises an opening in said base and a resilient seal covering said opening, said resilient seal being movable in response to a pressure difference between said sealed space and ambient pressure to allow fluid to pass through said opening.

7. The apparatus as claimed in claim 1 wherein one of said base and said cover has sealable openings through which electrical conductors may pass.

8. The apparatus as claimed in claim 1 wherein said base is formed from metal.

9. The apparatus as claimed in claim 1 wherein said base has means for mounting said apparatus to a battery mount.

10. The apparatus as claimed in claim 1 wherein said base has a transformer mount, for mounting a transformer of said energy conversion device.

11. The apparatus as claimed in claim 1 wherein said cover is formed from plastic.

12. The apparatus as claimed in claim 1 further comprising an energy conversion circuit mounted in an airspace inside said sealed space.

13. The apparatus as claimed in claim 12 wherein said energy conversion circuit includes a plurality of switching devices configured to reduce heat generation sufficient to permit said energy conversion circuit to operate while said apparatus is in an ambient temperature range between about −40 degrees centigrade to about +85 degrees centigrade.

14. The apparatus of claim 13 wherein said plurality of switching devices comprises a plurality of transistors connected in parallel.

15. The apparatus as claimed in claim 13 wherein said energy conversion circuit further includes a transformer configured to reduce heat generation sufficient to permit said energy conversion circuit to operate while said apparatus is in an ambient temperature range between about −40 degrees centigrade to about +85 degrees centigrade.

16. The apparatus as claimed in claim 1 wherein said apparatus has a generally rectangular parallelepiped shape.

17. The apparatus as claimed in claim 1 wherein said apparatus has a battery form factor enabling the apparatus to occupy a space occupiable by a battery.

18. The apparatus of claim 17 further comprising securing means for securing the apparatus in said space occupiable by a battery.

19. The apparatus as claimed in claim 12 wherein said energy conversion circuit includes a plurality of circuit boards and a vibration damper for dampening vibrations of said circuit boards.

20. The apparatus as claimed in claim 19 wherein said vibration damper includes supports extending between said circuit boards.

21. The apparatus as claimed in claim 12 wherein said energy conversion circuit includes a plurality of circuit boards and wherein mount includes holders in said base and in said cover for holding said circuit boards of said energy conversion device in spaced apart relation.

22. The apparatus as claimed in claim 21 wherein said holders permit one circuit board to move relative to the other, facilitating sealing between components on said circuit boards and said cover while permitting access to said components, from outside the cover.

23. The apparatus as claimed in claim 22 further comprising a vibration damper for dampening vibrations of said circuit boards.

24. The apparatus as claimed in claim 23 wherein said vibration damper includes a support extending between said circuit boards.

25. The apparatus as claimed in claim 24 wherein said support includes a guide and wherein at least one of said circuit boards has an opening for co-operating with said guide to guide said at least one circuit board in sliding movement relative to the other.

26. The apparatus as claimed in claim 12 wherein said energy conversion circuit includes an inverter.

27. The apparatus as claimed in claim 12 wherein said energy conversion circuit includes a charger.

28. The apparatus as claimed in claim 12 wherein said energy conversion device comprises a combination charger and inverter.
